(19) United States
(12) Patent Application Publication
(10) Pub. No.: US 2024/0243096 A1
(43) Pub. Date: Jul. 18, 2024

(54) SEMICONDUCTOR PACKAGE

(71) Applicant: SAMSUNG ELECTRONICS CO., LTD., Suwon-si (KR)

(72) Inventors: Moonyong Jang, Suwon-si (KR); Sangsub Song, Suwon-si (KR); Keunyoung Lee, Suwon-si (KR)

(21) Appl. No.: 18/413,115

(22) Filed: Jan. 16, 2024

(30) Foreign Application Priority Data
Jan. 16, 2023 (KR) 10-2023-0006319

(51) Int. Cl. H01L 25/065; H01L 23/00; H01L 23/498

(52) U.S. Cl. CPC H01L 25/0652; H01L 23/49816; H01L 24/48; H01L 24/32; H01L 24/33; H01L 24/49; H01L 24/73; H01L 2224/32145; H01L 2224/32225; H01L 2224/33181; H01L 2224/48145; H01L 2224/48227; H01L 2224/49052; H01L 2224/73215; H01L 2224/73265; H01L 2225/06562

(57) ABSTRACT

Embodiments of the present disclosure include a semiconductor package comprising a first substrate including a plurality of wires stacked in a plurality of layers in a vertical direction, a plurality of chip stack structures spaced apart from each other on the first substrate and arranged in a first direction, a processor chip disposed on the first substrate, and a chip-to-chip wire connecting a chip stack structure that is disposed closest to the processor chip among the plurality of chip stack structures, wherein each of the plurality of chip stack structures includes a plurality of semiconductor chips offset-stacked in the first direction and a plurality of wires connecting the plurality of semiconductor chips to one another.

### CROSS-REFERENCE

This application is based on and claims priority to and benefit under 35 U.S.C. § 119 to Korean Patent Application No. 10-2023-0006319, filed on Jan. 16, 2023, in the Korean Intellectual Property Office, the contents of which are incorporated by reference herein in their entirety.

### BACKGROUND

The present disclosure relates to a semiconductor package, and more particularly, to a semiconductor package having a processor chip and a chip stack structure.

Semiconductor packages can include an integrated circuit (IC) chip for use in various electronic products. A semiconductor package may be configured such that a semiconductor chip is mounted on a printed circuit board (PCB). Bonding wires may be used to electrically connect the semiconductor chip to the printed circuit board.

The demand for portable electronic devices is increasing. Accordingly, manufacturers continue to target the miniaturization and weight reduction of components mounted on electronic products. As the miniaturization and weight reduction of electronic components is achieved, semiconductor packages are designed to process high-capacity data while reducing size of the packages. Therefore, there is a need in the art for optimization of wire bonding between a chip stack structure and a processor chip for a highly integrated semiconductor package.

### SUMMARY

The present disclosure describes systems and methods for providing a connection between a chip stack structure and a processor chip. Some embodiments include reducing the number of wiring layers of a first substrate.

According to an aspect of the present disclosure, there is provided a semiconductor package.

The semiconductor package includes a first substrate comprising a plurality of wires stacked in a plurality of layers in a vertical direction, respectively, a plurality of chip stack structures spaced apart from each other on the first substrate and arranged in a first direction, a processor chip disposed on the first substrate, and a chip-to-chip wire interconnecting the processor and a chip stack structure disposed closest to the processor chip among the plurality of chip stack structures, wherein each of the plurality of chip stack structures includes a plurality of semiconductor chips offset-stacked in the first direction and a plurality of wires connecting the plurality of semiconductor chips to one another.

According to another aspect of the inventive concept, there is provided a semiconductor package including a plurality of wires comprising a first substrate including a first wiring and a second wiring, a first chip stack structure disposed on the first substrate and including a plurality of first semiconductor chips offset-stacked in a first direction, a second chip stack structure disposed on the first substrate spaced apart from the first chip stack structure in the first direction and including a plurality of second semiconductor chips offset-stacked in the first direction, a processor chip disposed on the first substrate and spaced apart from the first chip stack structure, an external connection bump disposed on a bottom surface of the first substrate, a first wire connecting a plurality of first semiconductor chips adjacent to each other in the first chip stack structure, a second wire connecting a plurality of second semiconductor chips adjacent to each other in the second chip stack structure, and a chip-to-chip wire interconnecting the processor chip and the first chip stack structure, wherein the processor chip includes a first processor chip pad, a second processor chip pad, and a third processor chip pad, and the second processor chip pad is electrically connected to the chip-to-chip wire.

According to another aspect of the inventive concept, there is provided a semiconductor package including a first substrate including a plurality of wires comprising a first wiring and a second wiring, a first chip stack structure disposed on the first substrate and including a plurality of first semiconductor chips offset-stacked in a first direction, a second chip stack structure disposed on the first substrate spaced apart from the first chip stack structure in the first direction and including a plurality of second semiconductor chips offset-stacked in the first direction, a processor chip disposed on the first substrate and spaced apart from the first chip stack structure, an external connection bump disposed on a bottom surface of the first substrate, a first wire connecting a plurality of first semiconductor chips adjacent to each other in the first chip stack structure, a second wire connecting a plurality of second semiconductor chips adjacent to each other in the second chip stack structure, and a chip-to-chip wire connecting the processor chip and the first chip stack structure, wherein the processor chip includes a first processor chip pad, a second processor chip pad, and a third processor chip pad, the second processor chip pad is electrically connected to the chip-to-chip wire, the first substrate includes a first substrate pad, a second substrate pad, and a third substrate pad formed on a top surface thereof, and wherein the second processor chip pad includes a pad for transmitting any one of a power signal, a ground signal, and a data signal.

Other features and aspects will be apparent from the following detailed description, the drawings, and the claims.

### BRIEF DESCRIPTION OF THE DRAWINGS

Embodiments of the inventive concept will be more clearly understood from the following detailed description taken in conjunction with the accompanying drawings:

FIG. 1 is a schematic cross-sectional view of a semiconductor package according to an embodiment;

FIG. 2 is a schematic cross-sectional view of a semiconductor package according to an embodiment;

FIG. 3 is a schematic cross-sectional view schematically showing a connection relationship of a semiconductor package according to an embodiment;

FIG. 4 is a schematic cross-sectional view of a semiconductor package according to an embodiment;

FIG. 5 is a schematic cross-sectional view of a semiconductor package according to an embodiment; and

FIG. 6 is a schematic cross-sectional view of a semiconductor package according to an embodiment.

### DETAILED DESCRIPTION

The present disclosure relates to semiconductor packages. Some embodiments of the disclosure include a method for optimization of a semiconductor package. For example, the method includes a technique for forming a connection between a chip stack structure and a processor chip. According to some embodiments of the disclosure, a method is described that reduces the number of wiring layers of a first substrate. In some cases, the number of wiring layers of a substrate may be reduced by directly connecting a chip stack structure and a processor chip through a chip-to-chip wire.

Conventional semiconductor packages may not be highly integrated. However, recently, a high integration of the semiconductor packages is needed. As such, the size of the conventional semiconductor package is high as the location and the structure of the various components in the package may not be optimized.

Embodiments of the present disclosure include systems and methods to form a connection between a chip stack structure and a processor chip. In some cases, the chip stack structure and the processor chip may be directly connected through a chip-to-chip wire. Accordingly, by directly connecting the chip stack structure and the processor chip, embodiments of the present disclosure can effectively reduce the number of wirings of a substrate. Moreover, by directly connecting the processor chip and the semiconductor chip stack structure, a faster transmission of the signal may be achieved.

Additionally, the semiconductor package includes a first substrate comprising a plurality of wires stacked in a plurality of layers in a vertical direction, respectively and a plurality of chip stack structures spaced apart from each other on the first substrate and arranged in a first direction. A processor chip is disposed on the first substrate and a chip-to-chip wire connects a chip stack structure that is disposed closest to the processor chip among the plurality of chip stack structures. In some cases, the plurality of chip stack structures comprises semiconductor chips that are offset-stacked in the first direction and a plurality of wires connect the semiconductor chips to one another. Moreover, the processor chip is located at an end of the first substrate in a second direction opposite to the first direction.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. The features described herein may be embodied in different forms and are not to be construed as being limited to the example embodiments described herein. Rather, the example embodiments described herein have been provided merely to illustrate some of the many possible ways of implementing the methods, apparatuses, and/or systems described herein that will be apparent after an understanding of the disclosure of this application.

The present disclosure may be modified in multiple alternate forms, and thus specific embodiments will be exemplified in the drawings and described in detail. In the present specification, when a component (or a region, a layer, a portion, etc.) is referred to as being “on,” “connected to,” or “coupled to” another component, it means that the component may be directly disposed on/connected to/coupled to the other component, or that a third component may be disposed therebetween.

Like reference numerals may refer to like components throughout the specification and the drawings. It is noted that while the drawings are intended to illustrate actual relative dimensions of a particular embodiment of the specification, the present disclosure is not necessarily limited to the embodiments shown. The term “and/or” includes all combinations of one or more of which associated configurations may define.

It will be understood that, although the terms “first,” “second,” etc. may be used herein to describe various components, these components should not necessarily be limited by these terms. These terms are only used to distinguish one component from another. For example, a first component could be termed a second component, and, similarly, a second component could be termed a first component, without departing from the scope of the inventive concept. The terms of a singular form may include plural forms unless the context clearly indicates otherwise.

Additionally, terms such as “below,” “under,” “on,” and “above” may be used to describe the relationship between components illustrated in the figures. The terms are used as a relative concept and are described with reference to the direction indicated in the drawings. It should be understood that the terms “comprise,” “include,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

Hereinafter, a method for forming a connection between a chip stack structure and a processor chip of an embodiment of the present disclosure will be described in detail with reference to the accompanying drawings. The same reference numerals are used for the same components in the drawings, and duplicate descriptions thereof are omitted.

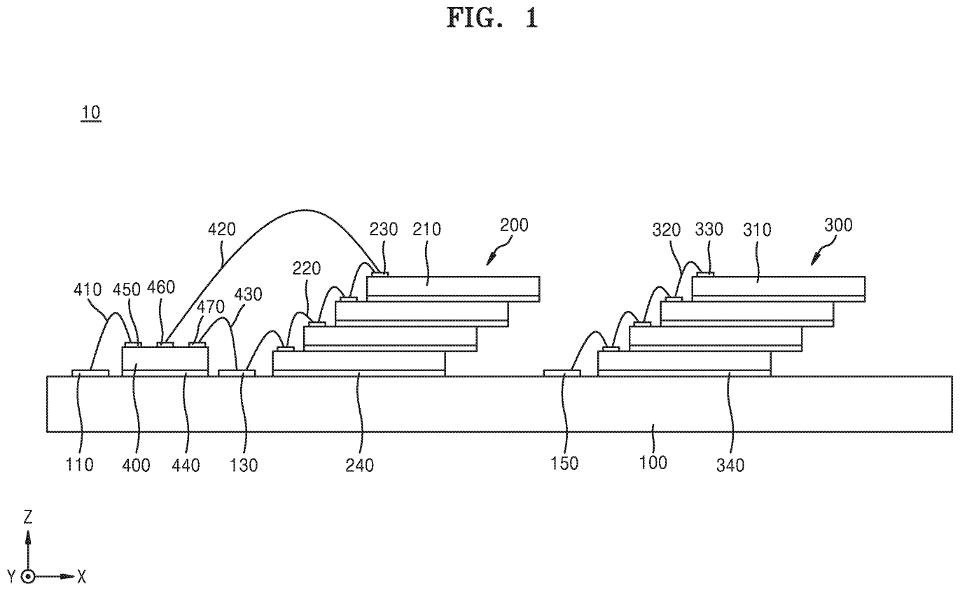

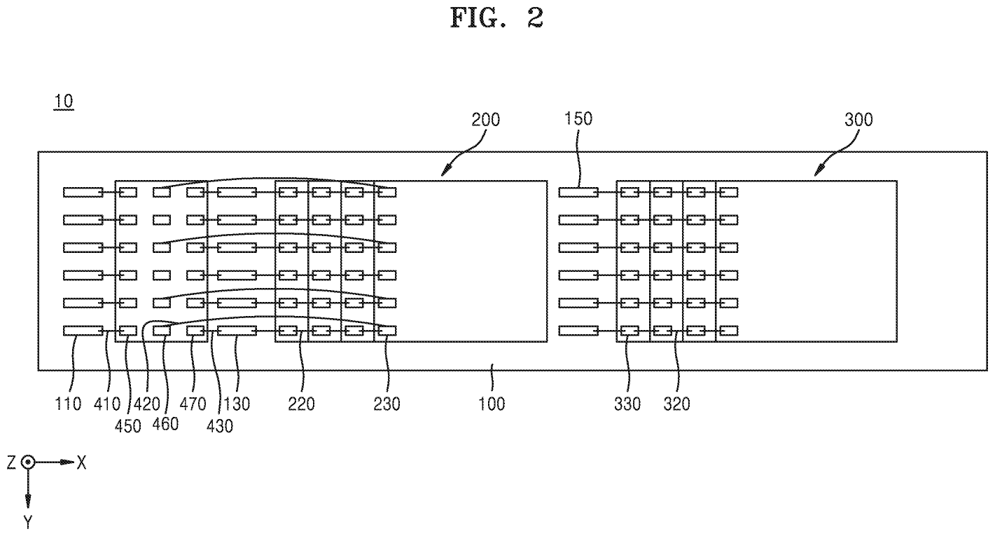

FIGS. 1 and 2 are schematic cross-sectional views of a semiconductor package according to an embodiment.

Referring to FIGS. 1 and 2, a semiconductor package 10 may include a first substrate 100, a first chip stack structure 200, a second chip stack structure 300, a processor chip 400, and a chip-to-chip wire 420.

The first substrate 100 is disposed below the first chip stack structure 200, the second chip stack structure 300, and the processor chip 400 and may be electrically connected to the second chip stack structure 300 and the processor chip 400. Thus, the first chip stack structure 200 and the second chip stack structure 300 may be mounted on the surface of the first substrate 100. According to an embodiment, the first substrate 100 may include, for example, a ceramic substrate, a printed circuit board (PCB), an organic substrate, an interposer substrate, etc.

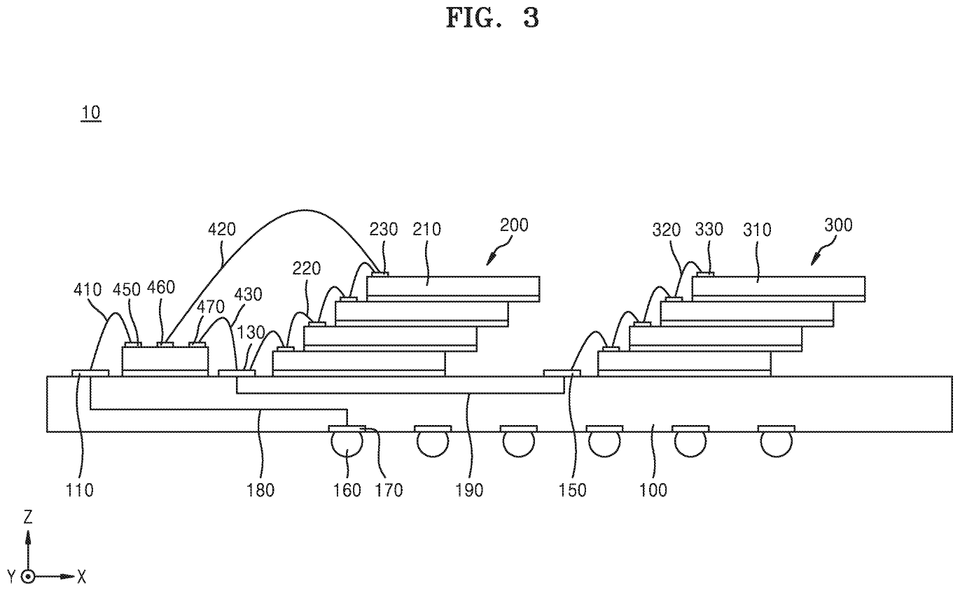

According to some embodiments, the first substrate 100 may include a redistribution structure. According to some embodiments, the first substrate 100 may include a body and wirings 180 and 190 (shown in FIG. 3). Portions of the wirings 180 and 190 may function as lower pads that are exposed from the bottom surface of the first substrate 100 and are used to mount external connection terminal 160 (shown in FIG. 3) thereon.

According to some embodiments, the X-axis direction and the Y-axis direction indicate directions parallel to the top surface or the bottom surface of the first substrate 100, and the X-axis direction and the Y-axis direction may be perpendicular to each other. The Z-axis direction may indicate a direction perpendicular to the top surface or the bottom surface of the first substrate 100.

In other words, the Z-axis direction may be a direction perpendicular to the X-Y plane.

According to some embodiments, a first horizontal direction, a second horizontal direction, and a vertical direction may be described as follows. The first horizontal direction may be the X-axis direction, the second horizontal direction may be the Y-axis direction, and the vertical direction may be the Z-axis direction.

The first chip stack structure 200 may be disposed on the first substrate 100. The first chip stack structure 200 may include first semiconductor chips 210, first semiconductor chip pads 230, and first wires 220. The first chip stack structure 200 may have a structure in which a plurality of first semiconductor chips 210 are offset-stacked in a first direction. Thus, the first chip stack structure 200 may have a structure in which first semiconductor chips 210 are stacked in a cascaded shape, i.e., a step shape in the first direction.

According to embodiments, the first direction may be the same direction as the first horizontal direction X. However, the present disclosure is not limited thereto, and the first direction may be a direction -X crossing the first horizontal direction X or a direction parallel to the second horizontal direction Y. According to example embodiments, the first semiconductor chips 210 may each be disposed such that an inactive surface of a semiconductor substrate faces the first substrate 100. In some cases, the bottom surface of each of the first semiconductor chips 210 may be a surface close to the inactive surface of the semiconductor substrate and the top surface of each of the first semiconductor chips 210 may be a surface close to an active surface of the semiconductor substrate.

As the first chip stack structure 200 is stacked in a stepped shape in the first direction, the top surface of each of the first semiconductor chips 210 may be partially exposed. Thus, a portion of the top surface of each of the first semiconductor chips 210 may not be covered by the first semiconductor chip stacked immediately thereon. When the first semiconductor chips 210 are stacked in the first direction, portions of the top surfaces of the first semiconductor chips 210 in a second direction, which is a direction perpendicular to and crossing the first direction, may be exposed upward.

The first semiconductor chip pads 230 may be disposed on the top surface of each of the first semiconductor chips 210. According to some embodiments, the first semiconductor chip pad 230 may be disposed on a region in which a portion of the top surface of the first semiconductor chip 210 is exposed upward. Accordingly, the first semiconductor chip pad 230 may be disposed at an end of the top surface of the first semiconductor chip 210 in the second direction. According to some embodiments, first semiconductor chip pads 230 may be provided and may be arranged on regions on the top surfaces of first semiconductor chips 210 exposed upward. According to example embodiments, the first semiconductor chip pads 230 may be arranged on the top surface of first semiconductor chip 210. According to some embodiments, the first semiconductor chip pads 230 may be arranged side-by-side on the top surface of the first semiconductor chip 210 in the second horizontal direction Y.

The first wires 220 may be formed on one side of the first chip stack structure 200. According to some embodiments, the first wires 220 may be formed in a direction in which the first semiconductor chip pads 230 are disposed. Accordingly, when the first chip stack structure 200 is stacked in the first direction, the first wires 220 may be disposed in the second direction, which is a direction perpendicular to and crossing the first direction. The first wires 220 may be disposed on the top surface of the first semiconductor chip 210 that is exposed upward.

The first wires 220 may be provided and may electrically interconnect first chip pads 230 arranged in different levels in the vertical direction Z. Thus, the first wires 220 may interconnect the first semiconductor chips 210 adjacent thereto. Also, the first wires 220 may be arranged in the second horizontal direction Y to electrically connect the first chip pads 230 having different levels in the vertical direction Z. Also, the first wires 220 may electrically connect the first substrate 100 and the lowermost first semiconductor chip 210. Accordingly, the first wire 220 may electrically connect the first semiconductor chip 210 and the first substrate 100 through a second substrate pad 130.

The first wire 220 may include gold (Au), aluminum (Al), or copper (Cu), but the present disclosure is not limited thereto.

An adhesive layer 240 may be located between the first substrate 100 and the lowermost of the first semiconductor chips 210 or stacked between first semiconductor chips 210. According to some embodiments, the adhesive layer 240 may be a layer configured to attach the first substrate 100 and the lowermost of the first semiconductor chips 210 or sequentially stacked between each of first semiconductor chips 210. Therefore, the first semiconductor chips 210 may be stacked on the first substrate 100 in a stacked shape by the adhesive layer 240.

For example, the lowermost of the first semiconductor chips 210, which is the first chip at the bottom of the first chip stack structure 200, may be adhered to and fixed to the top surface of the first substrate 100 through the adhesive layer 240. The first semiconductor chips 210 stacked on the top surface of the lowermost first semiconductor chip may be adhered to and fixed to the top surface of the lowermost first semiconductor chip 210 through the adhesive layer 240. In some cases, the first semiconductor chip stacked on the first semiconductor chips 210, which is stacked on the lowermost first semiconductor chip, may also be bonded and fixed to the top surface of the first semiconductor chip 210 directly therebelow through the adhesive layer 240.

The adhesive layers 240 may be a film having an adhesive characteristic. For example, the adhesive layers 240 may be a double-sided adhesive film. According to some embodiments, the adhesive layers 240 may be a tape-like material layer, a liquid coating curing material layer, or a combination thereof. In some cases, the adhesive layers 240 may include a thermal setting structure, a thermal plastic, a UV cure material, or a combination thereof. The adhesive layer 240 may be referred to as a die attach film (DAF) or a non-conductive film (NCF).

The first semiconductor chips 210 may be a semiconductor chip. According to embodiments, the first semiconductor chips 210 may be a memory chip or a logic chip. The memory chip may be, for example, a volatile memory chip like a dynamic random access memory (DRAM) or a static random access memory (SRAM) or a non-volatile memory chip like a phase-change random access memory (PRAM), a magneto-resistive random access memory (MRAM) a ferroelectric random access memory (FeRAM), or a resistive random access memory (RRAM). The logic chip may be, for example, a microprocessor like a central processing unit (CPU), a graphic processing unit (GPU), or an application processor (AP), an analog device, or a digital signal processor.

According to some embodiments, the first semiconductor chips 210 may be a NAND flash memory chip. Therefore, the first chip stack structure 200 may be a chip stack structure in which a plurality of NAND flash memory chips are offset-stacked in the first direction and mounted on the first substrate 100.

The second chip stack structure 300 may be disposed on the first substrate 100 and spaced apart from the first chip stack structure 200 in the first horizontal direction X. According to embodiments, the second chip stack structure 300 may be disposed to be spaced apart from the first chip stack structure 200 in the first direction. That is, the second chip stack structure 300 may be disposed on the side of the first chip stack structure 200 in the first direction. Additionally, the second chip stack structure 300 may be disposed on the first substrate 100 to be spaced apart from the first chip stack structure 200 in the first horizontal direction X with a third substrate pad 150 therebetween.

The second chip stack structure 300 may include second semiconductor chips 310, second semiconductor chip pads 330, and second wires 320. The second chip stack structure 300 may have a structure in which second semiconductor chips 310 are offset-stacked in the first direction.

The direction in which the second semiconductor chips 310 of the second chip stack structure 300 are offset-stacked may be substantially identical to the direction in which the plurality of first semiconductor chips 210 of the first chip stack structure 200 are offset-stacked. As a result of the offset-stacking, the second chip stack structure 300 may have a structure in which the plurality of second semiconductor chips 310 are stacked in a cascaded shape, i.e., a stepped shape in the first direction. The direction in which the first semiconductor chips 210 are offset-stacked may be identical to the direction in which the second semiconductor chips 310 are offset-stacked.

As the second chip stack structure 300 is stacked in a stepped shape in the first direction, the top surface of each of the second semiconductor chips 310 may be partially exposed. In some cases, a portion of the top surface of each of the second semiconductor chips 310 may not be covered by the second semiconductor chip 310 stacked immediately thereon. When the second semiconductor chips 310 are stacked in the first direction, portions of the top surfaces of the second semiconductor chips 310 in a second direction crossing the first direction may be exposed upward.

According to an example embodiment, the second semiconductor chips 310 may each be disposed such that an inactive surface of a semiconductor substrate faces the first substrate 100. In some cases, the bottom surface of each of the second semiconductor chips 310 may be a surface close to the inactive surface of the semiconductor substrate and the top surface of each of the second semiconductor chips 310 may be a surface close to an active surface of the semiconductor substrate.

The second semiconductor chip pads 330 may be disposed on the top surface of each of the second semiconductor chips 310. According to some embodiments, the second semiconductor chip pads 330 may be disposed on a region in which a portion of the top surface of the second semiconductor chip 310 is exposed upward. According to some embodiments, second semiconductor chip pads 330 may be provided and may be arranged in regions on the top surfaces of the second semiconductor chips 310 exposed upward. According to an example embodiment, the second semiconductor chip pads 330 may be arranged on the top surface of one second semiconductor chip 310. According to some embodiments, the second semiconductor chip pads 330 may be arranged side-by-side on the top surface of the second semiconductor chip 310 in the second horizontal direction Y.

The second wires 320 may be formed on one side of the second chip stack structure 300. According to some embodiments, the second wires 320 may be formed on the side of each of the second semiconductor chips 310 in the second direction.

Second wires 320 may be provided and some of the plurality of second wires 320 may electrically connect the third substrate pad 150 and the second semiconductor chip pads 330. Additionally, some of the second wires 320 may electrically connect second semiconductor chip pads 330 having different levels in the vertical direction Z. In some cases, the second wires 320 may be arranged in the second horizontal direction Y and electrically connect the third substrate pad 150 and the second semiconductor chip pad 330. Additionally, the second wires 320 may electrically connect the second semiconductor chip pads 330 having different levels in the vertical direction Z.

Since the material and the configuration of the second wires 320 are substantially the same as or similar to those of the first wires 220, detailed descriptions thereof will be omitted.

The adhesive layers 340 may be located between the first substrate 100 and the lowermost second semiconductor chip. Additionally, the adhesive layers 340 may be located between stacked second semiconductor chips 310. Since the material and the configuration of the adhesive layers 340 may be substantially the same as or similar to those of the adhesive layer 240 described in the first chip stack structure 200, detailed descriptions thereof will be omitted.

For example, the second chip stack structure 300 may be adhered to and fixed to the top surface of the first substrate 100 through the adhesive layer 340, and each of the second semiconductor chips 310 may also be adhered and fixed onto the second semiconductor chip 310 immediately therebelow through the adhesive layer 340.

The second semiconductor chip 310 may be a semiconductor chip. According to some embodiments, the second semiconductor chip 310 may be a memory chip or a logic chip. According to some embodiments, the second semiconductor chip 310 may be a NAND flash memory chip. Therefore, the second chip stack structure 300 may be a chip stack structure in which a plurality of NAND flash memory chips are offset-stacked in the first direction and mounted on the first substrate 100.

According to some embodiments, the second semiconductor chip 310 may be same as the first semiconductor chip 210. However, the inventive concept is not limited thereto, and the second semiconductor chip 310 and the first semiconductor chip 210 may be different types of chips.

A plurality of chip stack structures may be mounted on the top surface of the first substrate 100. According to some embodiments, n chip stack structures may be provided. n may be an integer equal to or greater than 1.

The processor chip 400 may be mounted on the top surface of the first substrate 100. The processor chip 400 may be adhered to the top surface of the first substrate 100 through an adhesive layer 440. The processor chip 400 may be disposed on the first substrate 100 such that an inactive surface of a semiconductor substrate faces the first substrate 100.

The processor chip 400 may be disposed on the side of the first chip stack structure 200 in the second direction. The processor chip 400 may be disposed at an end of the first substrate 100 in the second direction. The processor chip 400 may be disposed on the side of the first chip stack structure 200 on which the first wires 220 are formed.

The processor chip 400 may include an integrated circuit. For example, the processor chip 400 may be a logic chip including a logic circuit. The logic chip may be a controller that controls memory chips. The processor chip 400 may be a processor chip like an ASIC serving as a host, e.g., a CPU, a GPU, and a system on chip (SoC).

A plurality of processor chip pads 450, 460, and 470 may be arranged on the top surface of the processor chip 400.

According to some embodiments, the plurality of processor chip pads 450, 460, and 470 may include input/output terminals performing a power pin function, input/output terminals performing a ground pin function, or input/output terminals performing a data pin function.

According to an embodiment, a first processor chip pad 450 may be located at an end of the top surface of the processor chip 400 in the second direction. The first processor chip pad 450 may be electrically connected to a first substrate pad 110 through a third wire 410.

A second processor chip pad 460 may be located at the center of the top surface of the processor chip 400. The second processor chip pad 460 may be electrically connected to the first chip stack structure 200 through a chip-to-chip wire 420.

According to some embodiments, the second processor chip pad 460 may include a pad transmitting any one of a power signal, a ground signal, and a data signal.

According to some embodiments, the chip-to-chip wire 420 is connected to the second processor chip pad 460 and may be electrically connected to any one of the first semiconductor chip pads 230 in the first chip stack structure 200. The first semiconductor chip pads 230 may be first semiconductor chip pads having different levels in the vertical direction Z.

As a result, the first chip stack structure 200 may be connected to the processor chip 400 without passing through wires in the first substrate 100. Therefore, the number of layers of wires needed in the first substrate 100 may be reduced.

A third processor chip pad 470 may be located at an end of the top surface of the processor chip 400 in the first direction X. The third processor chip pad 470 may be electrically connected to the second substrate pad 130 through a fourth wire 430.

A plurality of first processor chip pads 450, a plurality of second processor chip pads 460, and a plurality of third processor chip pads 470 may be provided. Additionally, the plurality of first processor chip pads 450, the plurality of second processor chip pads 460, and the plurality of third processor chip pads 470 may be arranged side-by-side on the first substrate 100 in the second horizontal direction Y.

A plurality of substrate pads 110, 130, and 150 may be arranged on a top surface of the first substrate 100. A plurality of first substrate pads 110, a plurality of second substrate pads 130, and a plurality of third substrate pads 150 may be provided. According to some embodiments, the plurality of first substrate pads 110, the plurality of second substrate pads 130, and the plurality of third substrate pads 150 may be arranged side-by-side on the first substrate 100 in the second horizontal direction Y.

The first substrate pad 110 may be disposed at an end of the top surface of the first substrate 100 in the first direction. The first substrate pad 110 may be electrically connected to the third wire 410.

The second substrate pad 130 may be disposed between the processor chip 400 and the first chip stack structure 200 on the top surface of the first substrate 100. The second substrate pad 130 may be electrically connected to the fourth wire 430.

The third substrate pad 150 may be disposed between the first chip stack structure 200 and the second chip stack structure 300. The third substrate pad 150 may be disposed on the top surface of the first substrate 100. The third substrate pad 150 may be electrically connected to the second wire 320.

FIG. 3 is a schematic cross-sectional view schematically showing a connection relationship of a semiconductor package according to an embodiment. Hereinafter, descriptions identical to those given above with reference to FIGS. 1 and 2 will be omitted.

Referring to FIG. 3, the semiconductor package 10 may further include external connection terminals 160. Additionally, the first substrate 100 may further include wirings 180 and 190 formed therein.

The first chip stack structure 200 may include the plurality of first semiconductor chip pads 230 and the plurality of first wires 220. Similarly, the second chip stack structure 300 may include the plurality of second semiconductor chip pads 330 and the plurality of second wires 320.

According to some embodiments, the plurality of first semiconductor chip pads 230 may form a first signal and the plurality of second semiconductor chip pads 330 may form a second signal. The plurality of first semiconductor chip pads 230 may be connected to the plurality of first wires 220 and the plurality of second semiconductor chip pads 330 may be connected to the plurality of second wires 320. A first signal may be transmitted to a stacked structure through the plurality of first wires 220 and a second signal may be transmitted to the stacked structure through the plurality of second wires 320.

The wirings 180 and 190 in the first substrate 100 may be formed in a plurality of layers in the vertical direction Z in the first substrate 100. According to some embodiments, the wirings 180 and 190 may be formed in n layers. According to some exemplary embodiments, the wirings 180 and 190 may form two layers.

In some cases, the lowermost wire of the wirings 180 and 190 is referred to as a first wiring 180 and a wire located on the first wiring 180 is referred to as a second wiring 190. The first wiring 180 may electrically connect the first substrate pad 110 and an external connection bump terminal 160. Additionally, the second wiring 190 may electrically connect the second substrate pad 130 and the third substrate pad 150. As the second substrate pad 130 and the third substrate pad 150 are electrically connected to each other by the second wiring 190, the second chip stack structure 300 and the processor chip 400 may be electrically connected to each other.

As a result, the electrical connection within the semiconductor package 10 may be established through the first wiring 180 and the second wiring 190.

The external connection terminal 160 may be located on the bottom surface of the first substrate 100. The external connection terminal 160 may be electrically connected to an external device, e.g., a motherboard, a PCB, a package substrate, etc. The external connection terminal 160 may be electrically connected to wiring patterns formed in the first substrate 100 through lower pads 170 attached to the bottom surface of the first substrate 100.

The external connection terminal 160 may include solder balls. However, according to an embodiment, the external connection terminal 160 may include pillars and solders. The external connection terminal 160 may include at least one of copper (Cu), silver (Ag), gold (Au), and tin (Sb).

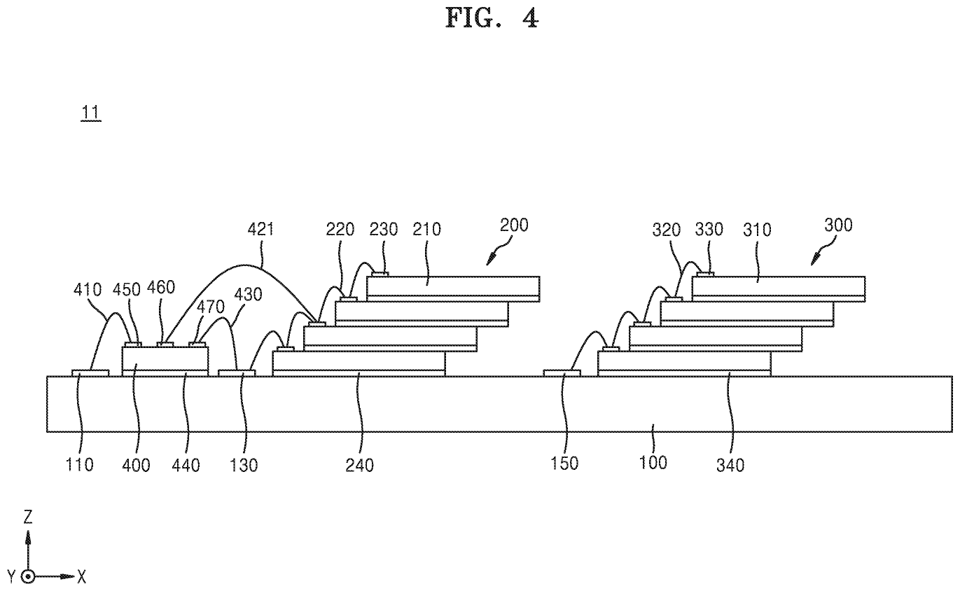

FIG. 4 is a schematic cross-sectional view of a semiconductor package according to an embodiment. Hereinafter, repeated descriptions of the semiconductor package 10 of FIG. 1 and a semiconductor package 11 of FIG. 4 will be omitted and differences therebetween will be provided.

Referring to FIG. 4, the semiconductor package 11 may include the first substrate 100, the first chip stack structure 200, the second chip stack structure 300, the processor chip 400, and a chip-to-chip wire 421.

The chip-to-chip wire 421 may be electrically connected to any one of the first semiconductor chips 210. According to some embodiments, the chip-to-chip wire 421 may be electrically connected to the first semiconductor chips 210. In some cases, the chip-to-chip wire 421 may be electrically connected to any one of the first semiconductor chips other than the uppermost first semiconductor chip 210.

In some cases, the chip-to-chip wire 421 may be electrically connected to the first semiconductor chip pad 230 formed on the first semiconductor chip 210. In some cases, the chip-to-chip wire 421 may be electrically connected to any one of the first semiconductor chip pads 230 that is not located at the topmost level in the vertical direction Z.

When the chip-to-chip wire 421 has the stated connection relationship, the length of the chip-to-chip wire 421 may be reduced. Accordingly, by connecting the chip-to-chip wire and the first semiconductor chip pad, embodiments of the present disclosure can perform a faster transmission of a signal.

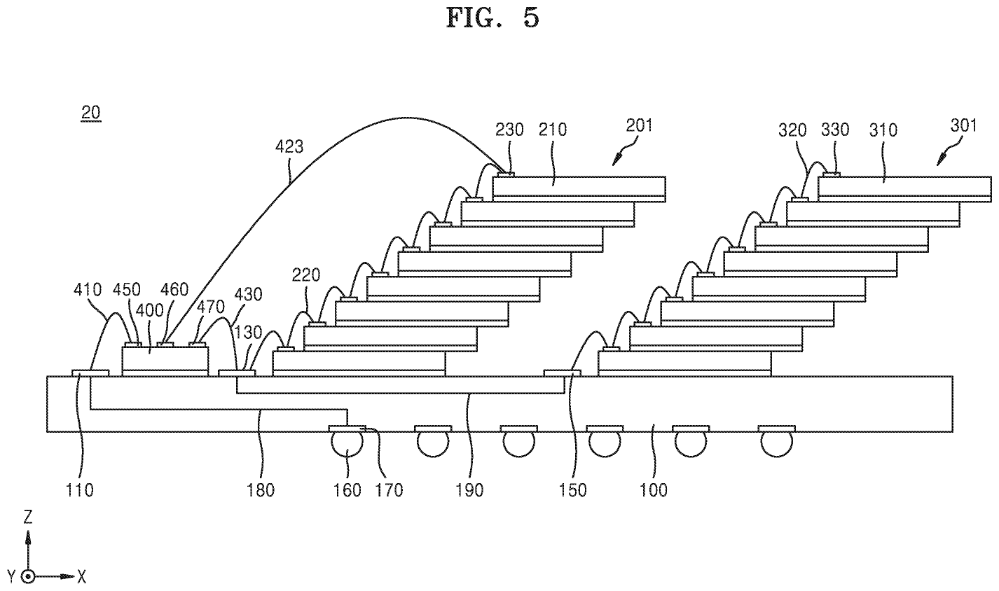

FIG. 5 is a schematic cross-sectional view of a semiconductor package according to an embodiment. Hereinafter, repeated descriptions of the semiconductor package 10 of FIG. 1 and a semiconductor package 20 of FIG. 5 will be omitted and differences therebetween will be provided.

Referring to FIG. 5, the semiconductor package 20 may include the first substrate 100, the first chip stack structure 201, the second chip stack structure 301, the processor chip 400, and a chip-to-chip wire 423.

According to some embodiments, the first chip stack structure 201 may include eight first semiconductor chips 210, and the second chip stack structure 301 may include eight second semiconductor chips 310.

According to some embodiments, the processor chip 400 and the first chip stack structure 201 may be electrically connected to each other through the uppermost first semiconductor chip 210, the chip-to-chip wire 423, and the second processor chip pad 460.

Additionally, the second chip stack structure 301 may be electrically connected to the processor chip 400 through the third substrate pad 150, the second wiring 190, the second substrate pad 130, the fourth wire 430, and the third processor chip pad 470.

The external connection terminal 160 may be electrically connected to the processor chip 400 through the lower pad 170, the first wiring 180, the first substrate pad 110, the third wire 410, and the first processor chip pad 450.

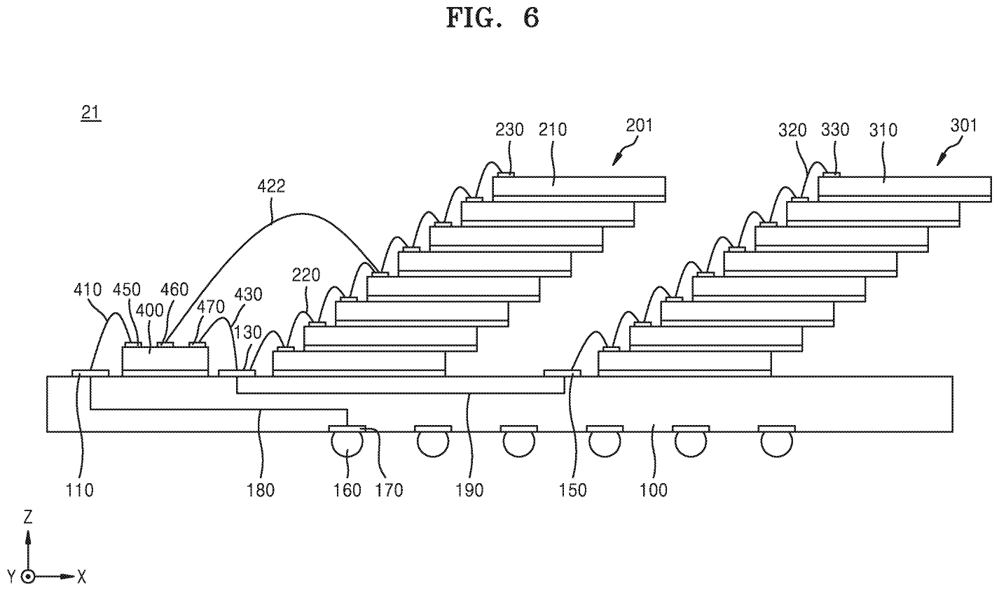

FIG. 6 is a schematic cross-sectional view of a semiconductor package according to an embodiment. Hereinafter, repeated descriptions of the semiconductor package 20 of FIG. 5 and a semiconductor package 21 of FIG. 6 will be omitted and differences therebetween will be provided.

Referring to FIG. 6, the semiconductor package 21 may include the first substrate 100, the first chip stack structure 201, the second chip stack structure 301, the processor chip 400, and a chip-to-chip wire 422.

According to some embodiments, the chip-to-chip wire 422 may be electrically connected to any one of the first semiconductor chips 210 arranged in the first chip stack structure 201. For example, the chip-to-chip wire 422 may be electrically connected to the first semiconductor chip 210 that is stacked fourth from the first substrate 100. In some cases, the first semiconductor chip 210 that is stacked in the fourth place may be electrically connected to the processor chip 400 through the first semiconductor chip pad 230, the chip-to-chip wire 422, and the second processor chip pad 460.

Additionally, the second chip stack structure 301 may be electrically connected to the processor chip 400 through the third substrate pad 150, the second wiring 190, the second substrate pad 130, the fourth wire 430, and the third processor chip pad 470.

The external connection terminal 160 may be electrically connected to the processor chip 400 through the lower pad 170, the first wiring 180, the first substrate pad 110, the third wire 410, and the first processor chip pad 450.

While the inventive concept has been particularly shown and described with reference to embodiments thereof, it will be understood by those of ordinary skill in the art that various changes in form and details may be made therein without departing from the spirit and scope of the inventive concept as defined by the following claims.

The processes discussed above are intended to be illustrative and not limiting. One skilled in the art would appreciate that the steps of the processes discussed herein may be omitted, modified, combined, and/or rearranged, and any additional steps may be performed without departing from the scope of the invention. More generally, the above disclosure is meant to be exemplary and not limiting. Only the claims that follow are meant to set bounds as to what the present invention includes. Furthermore, it should be noted that the features and limitations described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted, the systems and/or methods described above may be applied to, or used in accordance with, other systems and/or methods.

What is claimed is:

1. A semiconductor package comprising:
a first substrate comprising a plurality of wires stacked in a plurality of layers in a vertical direction, respectively;
a plurality of chip stack structures spaced apart from each other on the first substrate and arranged in a first direction;
a processor chip disposed on the first substrate; and
a chip-to-chip wire interconnecting the processor chip and a chip stack structure that is disposed closest to the processor chip among the plurality of chip stack structures,
wherein each of the plurality of chip stack structures comprises a plurality of semiconductor chips offset-stacked in the first direction and a plurality of wires connecting the plurality of semiconductor chips to one another.

2. The semiconductor package of claim 1, wherein a first processor chip pad, a second processor chip pad, and a third processor chip pad are arranged on a top surface of the processor chip,
the first processor chip pad, the second processor chip pad, and the third processor chip pad are spaced apart from one another in the first direction.

3. The semiconductor package of claim 2, wherein the second processor chip pad is connected to the first chip stack structure through a chip-to-chip wire.

4. The semiconductor package of claim 2, wherein the second processor chip pad comprises a pad for transmitting any one of a power signal, a ground signal, and a data signal.

5. The semiconductor package of claim 1, wherein the number of chip stack structures provided is 2.

6. The semiconductor package of claim 1, wherein:
an external connection bump is formed on a bottom surface of the first substrate, and
a first substrate pad, a second substrate pad, and a third substrate pad are formed on a top surface of the first substrate.

7. The semiconductor package of claim 6, wherein:
the plurality of wires comprises a first wiring that electrically connects a first processor chip pad and the external connection bump and a second wiring that electrically connects a third processor chip pad and a second chip stack structure.

8. The semiconductor package of claim 7, wherein the first processor chip pad is electrically connected to the first substrate pad through a third wire.

9. The semiconductor package of claim 7, wherein the third processor chip pad is electrically connected to the second substrate pad through a fourth wire.

10. The semiconductor package of claim 1, wherein the chip-to-chip wire is electrically connected to an uppermost semiconductor chip in a first chip stack structure from among the plurality of chip stack structures.

11. A semiconductor package comprising:
a first substrate including a plurality of wires comprising a first wiring and a second wiring;
a first chip stack structure disposed on the first substrate and comprising a plurality of first semiconductor chips offset-stacked in a first direction;
a second chip stack structure disposed on the first substrate spaced apart from the first chip stack structure in the first direction and comprising a plurality of second semiconductor chips offset-stacked in the first direction;
a processor chip disposed on the first substrate and spaced apart from the first chip stack structure;
an external connection bump disposed on a bottom surface of the first substrate;
a first wire connecting the plurality of first semiconductor chips adjacent to each other in the first chip stack structure;
a second wire connecting the plurality of second semiconductor chips adjacent to each other in the second chip stack structure; and
a chip-to-chip wire connecting the processor chip and the first chip stack structure,
wherein the processor chip comprises a first processor chip pad, a second processor chip pad, and a third processor chip pad, and
the second processor chip pad is electrically connected to the chip-to-chip wire.

12. The semiconductor package of claim 11, wherein the second processor chip pad comprises a pad for transmitting any one of a power signal, a ground signal, and a data signal.

13. The semiconductor package of claim 11, further comprising a first substrate pad, a second substrate pad, and a third substrate pad positioned on the first substrate.

14. The semiconductor package of claim 13, wherein:
the first substrate pad is electrically connected to the first processor chip pad through a third wire,
the second substrate pad is electrically connected to the third processor chip pad through a fourth wire,
the first substrate pad is electrically connected to the external connection bump through the first wiring, and
the second substrate pad is electrically connected to the second chip stack structure through the second wiring.

15. The semiconductor package of claim 11, wherein each of the chip stack structures include four semiconductor chips.

16. The semiconductor package of claim 11, wherein each of the chip stack structures include eight semiconductor chips.

17. The semiconductor package of claim 11, wherein the chip-to-chip wire is electrically connected to an uppermost first semiconductor chip from among the first semiconductor chips of the chip stack structure.

18. A semiconductor package comprising:
a first substrate including a plurality of wires comprising a first wiring and a second wiring;
a first chip stack structure disposed on the first substrate and comprising a plurality of first semiconductor chips offset-stacked in a first direction;
a second chip stack structure disposed on the first substrate, spaced apart from the first chip stack structure in the first direction, and comprising a plurality of second semiconductor chips offset-stacked in the first direction;
a processor chip disposed on the first substrate and spaced apart from the first chip stack structure;
an external connection bump disposed on a bottom surface of the first substrate;
a first wire connecting the plurality of first semiconductor chips adjacent to each other in the first chip stack structure;
a second wire connecting the plurality of second semiconductor chips adjacent to each other in the second chip stack structure; and
a chip-to-chip wire connecting the processor chip and the first chip stack structure,
wherein the processor chip comprises a first processor chip pad, a second processor chip pad, and a third processor chip pad,
the second processor chip pad is electrically connected to the chip-to-chip wire,
the first substrate comprises a first substrate pad, a second substrate pad, and a third substrate pad formed on a top surface thereof, and
wherein the second processor chip pad comprises a pad for transmitting any one of a power signal, a ground signal, and a data signal.

19. The semiconductor package of claim 18, wherein:
the first substrate pad is electrically connected to the first processor chip pad through a third wire,
the second substrate pad is electrically connected to the third processor chip pad through a fourth wire,
the first substrate pad is electrically connected to the external connection bump through the first wiring, and
the second substrate pad is electrically connected to the second chip stack structure through the second wiring.

20. The semiconductor package of claim 18, wherein each of the chip stack structures include four semiconductor chips.
